(19) United States
(12) Patent Application Publication
(10) Pub. No.: US 2026/0052688 A1
(43) Pub. Date: Feb. 19, 2026

(54) SEMICONDUCTOR DEVICE AND METHOD OF MANUFACTURING THE SEMICONDUCTOR DEVICE

(71) Applicant: SK hynix Inc., Icheon-si Gyeonggi-do (KR)

(72) Inventors: Rho Gyu KWAK, Icheon-si Gyeonggi-do (KR); Jung Shik JANG, Icheon-si Gyeonggi-do (KR); Won Geun CHOI, Icheon-si Gyeonggi-do (KR); Mi Seong PARK, Icheon-si Gyeonggi-do (KR); In Su PARK, Icheon-si Gyeonggi-do (KR); Na Yeong YANG, Icheon-si Gyeonggi-do (KR); Seok Min CHOI, Icheon-si Gyeonggi-do (KR)

(73) Assignee: SK hynix Inc., Icheon-si Gyeonggi-do (KR)

(21) Appl. No.: 18/962,090

(22) Filed: Nov. 27, 2024

(30) Foreign Application Priority Data
Aug. 14, 2024 (KR) 10-2024-0108957

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A semiconductor device includes a first gate structure including alternately stacked first conductive layers and first insulating layers, a second gate structure positioned on the first gate structure and including alternately stacked second conductive layers and second insulating layers, and channel structures extending through the first gate structure and the second gate structure and having a first width. The semiconductor device also includes first contact vias extending through the second gate structure and into the first gate structure, being respectively connected to the first conductive layers, respectively including first sub-vias merged in a horizontal direction, and having a second width greater than the first width. The semiconductor device further includes second contact vias extending into the second gate structure, being respectively connected to the second conductive layers, respectively including second sub-vias merged in the horizontal direction, and having a third width greater than the first width.

### CROSS-REFERENCE TO RELATED APPLICATION

The present application claims priority under 35 U.S.C. § 119 (a) to Korean Patent Application No. 10-2024-0108957, filed in the Korean Intellectual Property Office on Aug. 14, 2024, which application is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in the integration degree of semiconductor devices in which memory cells are formed as a single layer on a substrate reaches a limit, three-dimensional semiconductor devices in which memory cells are stacked on a substrate are being proposed. In addition, various structures and manufacturing methods are being developed to improve operation reliability of the semiconductor devices.

### SUMMARY

According to an embodiment of the present disclosure, a semiconductor device may include a first gate structure including first conductive layers and first insulating layers alternately stacked with each other, a second gate structure positioned on the first gate structure and the second gate structure including second conductive layers and second insulating layers alternately stacked with each other, and channel structures extending through the first gate structure and the second gate structure and the channel structures having a first width. The semiconductor device may also include first contact vias extending through the second gate structure and into the first gate structure, the first contact vias respectively connected to the first conductive layers, the first contact vias respectively including first sub-vias merged in a horizontal direction, and the first contact vias having a second width greater than the first width, and second contact vias extending into the second gate structure, the second contact vias respectively connected to the second conductive layers, the second contact vias respectively including second sub-vias merged in the horizontal direction, and the second contact vias having a third width greater than the first width.

According to an embodiment of the present disclosure, a method of manufacturing a semiconductor device may include forming a first stack by alternately stacking first material layers and second material layers, forming a second stack by alternately stacking third material layers and fourth material layers on the first stack, and forming first sub-via holes extending through the second stack. The method may also include forming preliminary first via holes by expanding the first sub-via holes so that at least two of the first sub-via holes are interconnected, forming first via holes of different depths by extending the preliminary first via holes into the first stack, and forming first contact vias in the first via holes.

According to an embodiment of the present disclosure, a method of manufacturing a semiconductor device may include forming a first stack, forming a second stack on the first stack, forming first sub-via holes extending through the second stack, forming a third stack on the second stack, forming second sub-via holes connected to the first sub-via holes through the third stack, and forming a protective layer on the third stack. The method may also include forming fourth sub-via holes connected to the second sub-via holes, respectively through the protective layer, forming a first opening by expanding the fourth sub-via holes by removing a portion of the protective layer so that at least two of the fourth sub-via holes are interconnected, and forming a preliminary first via hole by expanding the second sub-via holes and the first sub-via holes through the first opening.

### BRIEF DESCRIPTION OF THE DRAWINGS

FIGS. 1A and 1B are drawings illustrating a semiconductor device according to an embodiment of the present disclosure.

FIG. 2 is a drawing illustrating a semiconductor device according to an embodiment of the present disclosure.

FIG. 3 is a drawing illustrating a semiconductor device according to an embodiment of the present disclosure.

FIGS. 4A, 4B, 5A, 5B, 6A, 6B, 7A, 7B, 8A, 8B, 9A, 9B, 10A, and 10B are drawings illustrating a method of manufacturing a semiconductor device according to an embodiment of the present disclosure.

FIGS. 11A, 11B, 12A, 12B, 13A, 13B, 14A, and 14B are drawings illustrating a method of manufacturing a semiconductor device according to an embodiment of the present disclosure.

### DETAILED DESCRIPTION

An embodiment of the present disclosure provides a semiconductor device and a method of manufacturing the semiconductor device to have a stable structure and improved characteristics.

According to the present technology, a semiconductor device having a stable structure and improved reliability.

Hereinafter, embodiments according to the technical spirit of the present disclosure are described with reference to the accompanying drawings.

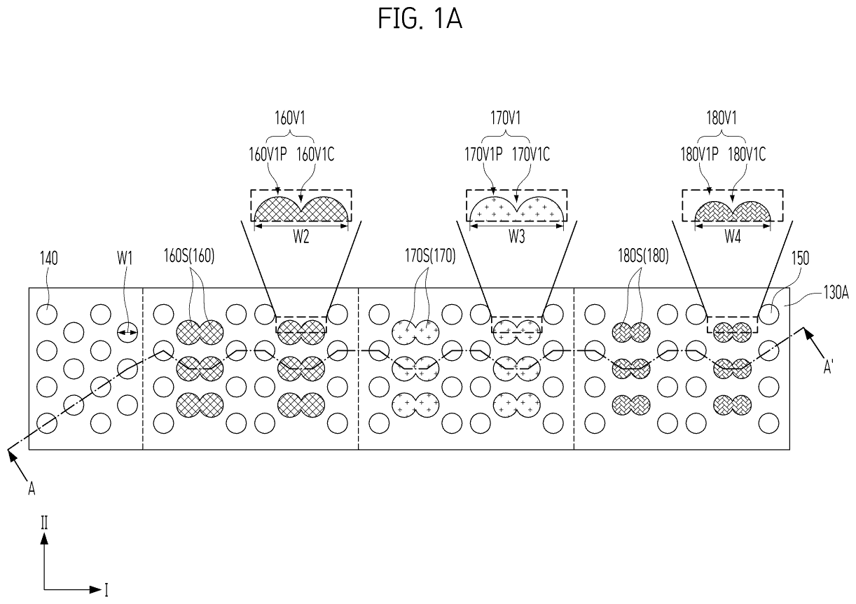

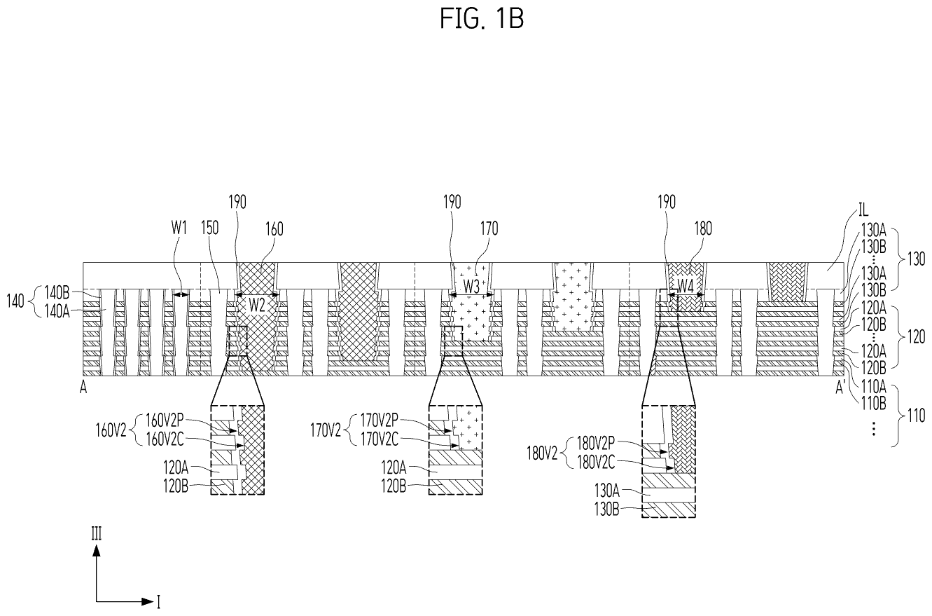

FIGS. 1A and 1B are drawings illustrating a semiconductor device according to an embodiment of the present disclosure. FIG. 1A is a plan view, and FIG. 1B is a cross-sectional view taken along line A-A′ of FIG. 1A.

Referring to FIGS. 1A and 1B, the semiconductor device may include a first gate structure 110, a second gate structure 120, a third gate structure 130, channel structures 140, supports 150, first contact vias 160, second contact vias 170, third contact vias 180, insulating spacers 190, and an interlayer insulating layer IL.

The first gate structure 110 may include alternately stacked first insulating layers 110A and first conductive layers 110B. The first conductive layers 110B may extend in a horizontal direction. For example, the first conductive layers 110B may extend in a first direction I. The first insulating layers 110A may include an insulating material, such as an oxide, and the first conductive layers 110B may include a conductive material, such as tungsten, molybdenum, or polysilicon.

The second gate structure 120 may be positioned on the first gate structure 110. The second gate structure 120 may include alternately stacked second insulating layers 120A and second conductive layers 120B. The second conductive layers 120B may extend in the horizontal direction. The second insulating layers 120A may include an insulating material, such as an oxide, and the second conductive layers 120B may include a conductive material, such as tungsten, molybdenum, or polysilicon.

The third gate structure 130 may be positioned on the second gate structure 120. The third gate structure 130 may include alternately stacked third insulating layers 130A and third conductive layers 130B. The third conductive layers 130B may extend in the horizontal direction. The third insulating layers 130A0 may include an insulating material, such as an oxide, and the third conductive layers 130B may include a conductive material, such as tungsten, molybdenum, or polysilicon.

The first conductive layers 110B, the second conductive layers 120B, and the third conductive layers 130B may be gate lines, such as source selection lines, word lines, or drain selection lines. A source selection transistor, a memory cell, or a drain selection transistor may be positioned in an area where the channel structure 140 and the first conductive layers 110B intersect, an area where the channel structure 140 and the second conductive layers 120B intersect, and an area where the channel structure 140 and the third conductive layers 130B intersect. For example, at least one source selection transistor, a plurality of memory cells, and at least one drain selection transistor stacked along the channel structure 140 may configure one memory string.

The channel structures 140 may extend through the first gate structure 110, the second gate structure 120, and the third gate structure 130. A cross-section of the channel structures 140 may have a tapered shape. For example, the channel structures 140 may have a width that decreases from an upper surface to a lower surface in the third gate structure 130. In addition, the channel structures 140 may have a width that decreases from an upper surface to a lower surface in the second gate structure 120. In addition, the channel structures 140 may have a width that decreases from an upper surface to a lower surface in the first gate structure 110. The channel structures 140 may have a first width W1 at its upper surface.

Each of the channel structures 140 may include a channel layer 140A and a memory layer 140B surrounding the channel layer 140A. Each of the channel structures 140 may further include an insulating core (not shown) in the channel layer 140A. Here, the channel layer 140A may include a semiconductor material, such as polysilicon or germanium. The insulating core may include an insulating material, such as an oxide.

The supports 150 may be positioned spaced apart from the channel structures 140. The supports 150 may extend through the first gate structure 110 and the second gate structure 120. The supports 150 may have a structure similar to the channel structures 140. For example, each of the supports 150 may include a dummy channel layer and a dummy memory layer surrounding the dummy channel layer. Each of the supports 150 may further include a dummy insulating core in the dummy channel layer. However, the present disclosure is not limited thereto, and the supports 150 may include an insulating material, such as an oxide. In addition, the supports 150 may include a conductive layer, such as tungsten, and an insulating layer surrounding the conductive layer.

The first contact vias 160 may extend through the third gate structure 130, the second gate structure 120, and into the first gate structure 110, and may be respectively connected to the first conductive layers 110B in that a different first contact via 160 is connected to each different first conductive layer 110B. Here, the first contact vias 160 may have different heights. Each of the first contact vias 160 may include first sub-vias 160S. Here, the first sub-vias 160S may be merged in the horizontal direction. The number of first sub-vias 160S merged in the horizontal direction may be two or more.

The first contact vias 160 may include a first uneven portion 160V1 on a sidewall in a plane. For example, a portion where the first sub-vias 160S are in contact with each other may configure a concave portion 160V1C of the first uneven portion 160V1. Each of the first sub-vias 160S may configure a convex portion 160V1P of the first uneven portion 160V1.

The first contact vias 160 may include a second uneven portion 160V2 on a side wall in a cross-section. For example, a portion corresponding to at least one of the first insulating layers 110A, the second insulating layers 120A, and/or the third insulating layers 130A through which the first contact vias 160 pass may configure a concave portion 160V2C of the second uneven portion 160V2. A portion corresponding to at least one of the first conductive layers 110B, the second conductive layers 120B, and/or the third conductive layers 130B through which the first contact vias 160 pass may configure a convex portion 160V2P of the second uneven portion 160V2. In other words, the second uneven portion 160V2 may include protrusions in which the first contact vias 160 protrude toward the first conductive layers 110B or the second conductive layers 120B. Because an etching rate of the insulating layers 110A, 120A, and 130A and an etching rate of material layers positioned in an area where the conductive layers 110B, 120B, and 130B are to be formed are different, the second uneven portions 160V2 may be formed in a process of manufacturing the semiconductor device.

The first contact vias 160 may have a second width W2. Here, the second width W2 may refer to a width of an upper surface in the third gate structure 130 of the first contact vias 160. The second width W2 may be greater than the first width W1 of the channel structures 140. The first contact vias 160 may include a conductive material, such as tungsten.

The second contact vias 170 may extend through the third gate structure 130 and into the second gate structure 120, and may be respectively connected to the second conductive layers 120B in that a different second contact via 170 is connected to each different second conductive layer 120B. Here, the second contact vias 170 may have different heights. The second contact vias 170 may include second sub-vias 170S. Here, the second sub-vias 170S may be merged in the horizontal direction. The number of second sub-vias 170S merged in the horizontal direction may be two or more.

The second contact vias 170 may include a third uneven portion 170V1 on a sidewall in a plane. For example, a portion where the second sub-vias 170S are in contact with each other may configure a concave portion 170V1C of the third uneven portion 170V1. Each of the second sub-vias 170S may configure a convex portion 170V1P of the third uneven portion 170V1.

The second contact vias 170 may include a fourth uneven portion 170V2 on a sidewall in a cross-section. For example, a portion corresponding to at least one of the second insulating layers 120A and/or the third insulating layers 130A through which the second contact vias 170 pass may configure a concave portion 170V2C of the fourth uneven portion 170V2. A portion corresponding to at least one of the second conductive layers 120B and/or the third conductive layers 130B through which the second contact vias 170 pass may configure a convex portion 170V2P of the fourth uneven portion 170V2.

The second contact vias 170 may have a third width W3. Here, the third width W3 may refer to a width of an upper surface in the third gate structure 130 of the second contact vias 170. The third width W3 may be substantially the same as the second width W2. The third width W3 may be greater than the first width W1. The second contact vias 170 may include a conductive material, such as tungsten.

The third contact vias 180 may extend into the third gate structure 130, and may be respectively connected to the third conductive layers 130B in that a different third contact via 180 is connected to each different third conductive layer 130B. Here, the third contact vias 180 may have different heights. The third contact vias 180 may include third sub-vias 180S. Here, the third sub-vias 180S may be merged in the horizontal direction. The number of third sub-vias 180S merged in the horizontal direction may be two or more.

The third contact vias 180 may include a fifth uneven portion 180V1 on a sidewall in a plane. For example, a portion where the third sub-vias 180S are in contact with each other may configure a concave portion 180V1C of the fifth uneven portion 180V1. Each of the second sub-vias 180S may configure a convex portion 180V1P of the fifth uneven portion 180V1.

The third contact vias 180 may include a sixth uneven portion 180V2 on a sidewall in a cross-section. For example, a portion corresponding to at least one of the third insulating layers 130A through which the third contact vias 180 pass may configure a concave portion 180V2C of the sixth uneven portion 180V2. A portion corresponding to at least one of the third conductive layers 130B through which the third contact vias 180 pass may configure a convex portion 180V2P of the sixth uneven portion 180V2. However, the present disclosure is not limited thereto, the third contact via 180 connected to the third conductive layer 130B positioned at the uppermost portion among the third contact vias 180 might not include the sixth uneven portion 180V2 on a sidewall in a vertical direction. This is because a preliminary via hole at a position where the third contact via 180 connected to the third conductive layer 130B positioned at the uppermost portion is to be formed is not extended in the vertical direction in the process of forming the semiconductor device.

The third contact vias 180 may have a fourth width W4. Here, the fourth width W4 may be greater than the first width W1. The fourth width W4 may refer to a width of an upper surface in the third gate structure 130 of the third contact vias 180. Here, the fourth width W4 may be less than the second width W2 and/or the third width W3. This is because the first and second contact vias 160 and 170 are formed through a process of removing and expanding sacrificial layers positioned in a stack of an area where the second and third gate structures 120 and 130 are to be formed in the process of manufacturing the semiconductor device. The third contact vias 180 may include a conductive material, such as tungsten.

The insulating spacers 190 may extend through the first gate structure 110, the second gate structure 120, and/or the third gate structure 130, and may surround a sidewall of the first contact vias 160, the second contact vias 170, and the third contact vias 180. The insulating spacers 190 may insulate the first, second, and third contact vias 160, 170, and 180 and the first, second, and third conductive layers 110B, 120B, and 130 except for the first, second, and third conductive layers 110B, 120B, and 130B connected to the first, second, and third contact vias 160, 170, and 180. For example, the insulating spacer 190 may insulate the first contact via 160 and the first, second, and third conductive layers 110B, 120B, and 130 except for the first conductive layer 110B connected to the first contact via 160. The insulating spacers 190 may include an insulating material, such as an oxide.

The interlayer insulating layer IL may be positioned on the third gate structure 130. The interlayer insulating layer IL may cover the channel structures 140 and the supports 150. The first, second, and third contact vias 160, 170, and 180 may extend through the interlayer insulating layer IL. The interlayer insulating layer IL may be used to protect the channel structures 140 and the supports 150 in a process of forming the first, second, and third contact vias 160, 170, and 180. The interlayer insulating layer IL may include an insulating material, such as an oxide.

According to the structure described above, the first contact vias 160 may include the merged first sub-vias 160S, the second contact vias 170 may include the merged second sub-vias 170S, and the third contact vias 180 may include the merged third sub-vias 180S. In addition, the first contact vias 160 may have different heights, the second contact vias 180 may have different heights, and the third contact vias 190 may have different heights.

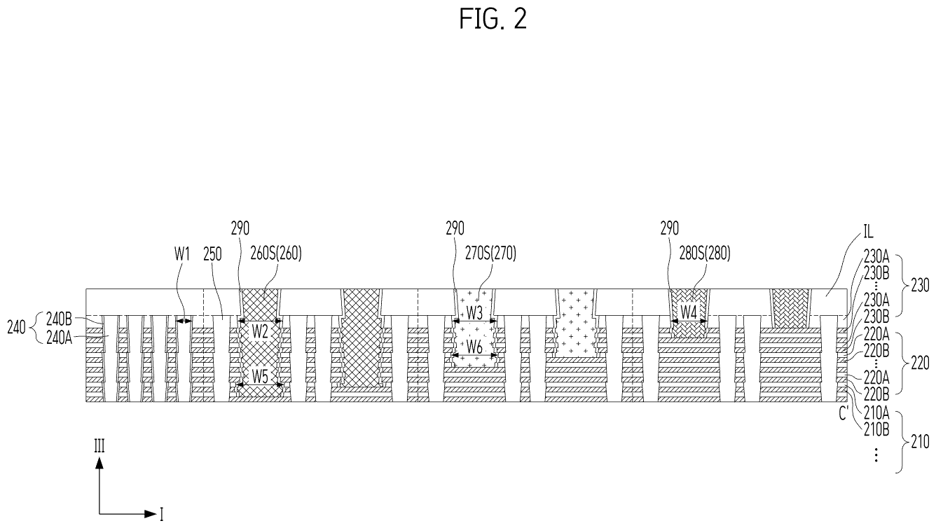

FIG. 2 is a drawing illustrating a semiconductor device according to an embodiment of the present disclosure. Hereinafter, content redundant with content already described above is omitted.

Referring to FIG. 2, the semiconductor device may include a first gate structure 210, a second gate structure 220, a third gate structure 230, channel structures 240, supports 250, first contact vias 260, second contact vias 270, third contact vias 280, insulating spacers 290, and an interlayer insulating layer IL.

The first gate structure 210 may include first insulating layers 210A and first conductive layers 210B alternately stacked with each other. The second gate structure 220 may be positioned on the first gate structure 210. The third gate structure 230 may be positioned on the second gate structure 220. The second gate structure 220 may include second insulating layers 220A and second conductive layers 220B alternately stacked with each other, and the third gate structure 230 may include third insulating layers 230A and third conductive layers 230B alternately stacked with each other. The first, second, and third insulating layers 210A, 220A, and 230A may include an insulating material, such as an oxide, and the first, second, and third conductive layers 210B, 220B, and 230B may include a conductive material, such as tungsten, molybdenum, or polysilicon.

The channel structures 240 may extend through the first gate structure 210, the second gate structure 220, and the third gate structure 230. A cross-section of the channel structures 240 may have a tapered shape. Each of the channel structures 240 may include a channel layer 240A and a memory layer 240B surrounding the channel layer 240A. Here, the channel layer 240A may include a semiconductor material, such as polysilicon or germanium.

The supports 250 may extend through the first gate structure 210 and the second gate structure 220. The supports 250 may include an insulating material, such as an oxide. In addition, the supports 250 may include a conductive layer, such as tungsten, and an insulating layer surrounding the conductive layer.

The first contact vias 260 may extend through the third gate structure 230, the second gate structure 220, and into the first gate structure 210, and may be respectively connected to the first conductive layers 210B in that a different first contact via 260 is connected to each different first conductive layer 210B. Here, the first contact vias 260 may have different heights. The first contact vias 260 may respectively include first sub-vias 260S merged in a horizontal direction.

The first contact vias 260 may have a second width W2 and/or a fifth width W5. The second width W2 may refer to a width of an upper surface in the third gate structure 230 of the first contact vias 260. The fifth width W5 may refer to a width of an upper surface in the first gate structure 210 of the first contact vias 260. Here, the fifth width W5 may be greater than the second width W2. The first contact vias 260 may include a conductive material, such as tungsten.

The second contact vias 270 may extend through the third gate structure 230 and into the second gate structure 220, and may be respectively connected to the second conductive layers 220B in that a different second contact via 270 is connected to each different second conductive layer 220B. Here, the second contact vias 270 may have different heights. The second contact vias 270 may include second sub-vias 270S merged in the horizontal direction.

The second contact vias 270 may have a third width W3 and/or a sixth width W6. The third width W3 may refer to a width of an upper surface in the third gate structure 230 of the second contact vias 270. The sixth width W6 may refer to a width of an upper surface in the second gate structure 220 of the second contact vias 270. Here, the sixth width W6 may be greater than the third width W3. This is because the second buffer layers formed in a second stack of an area where the second gate structure 220 is to be formed are removed and expanded in a process of forming the second contact vias 270. The second contact vias 270 may include a conductive material, such as tungsten.

The third contact vias 280 may extend into the third gate structure 230, and may be respectively connected to the third conductive layers 230B in that a different third contact via 280 is connected to each different third conductive layer 230B. Here, the third contact vias 280 may have different heights. The third contact vias 280 may include third sub-vias 280S merged in the horizontal direction.

The third contact vias 280 may have a fourth width W4. The fourth width W4 may refer to a width of an upper surface in the third gate structure 230 of the third contact vias 280. The third contact vias 280 might not have a width different from the fourth width W4 differently from the first and second contact vias 260 and 270. This is because third buffer layers might not be separately formed in a third stack of an area where the third gate structure 230 is to be formed in a process of forming the third contact vias 280. However, the present disclosure is not limited thereto, and when the third buffer layers are formed in the third stack, the width of the upper surface in the third gate structure 230 of the third contact vias 280 may vary by removing and expanding the third buffer layers. The third contact vias 280 may include a conductive material, such as tungsten.

The insulating spacers 290 may extend through the first gate structure 210, the second gate structure 220, and/or the third gate structure 230 and may surround a sidewall of the first contact vias 260, the second contact vias 270, and the third contact vias 280. The insulating spacers 290 may include an insulating material, such as an oxide.

The interlayer insulating layer IL may be positioned on the third gate structure 230. The interlayer insulating layer IL may cover the channel structures 240 and the supports 250. The first, second, and third contact vias 260, 270, and 280 may extend through the interlayer insulating layer IL. The interlayer insulating layer IL may include an insulating material, such as an oxide.

According to the structure described above, each of the first contact vias 260 may have the second width W2, which is the width of the upper surface in the third gate structure 230, and may have the fifth width W5, which is the width of the upper surface in the first gate structure 210. Each of the second contact vias 270 may have the third width W3, which is the width of the upper surface in the third gate structure 230, and may have the sixth width W6, which is the width of the upper surface in the second gate structure 220. Here, the fifth width W5 may be greater than the second width W2, and the sixth width W6 may be greater than the third width W3.

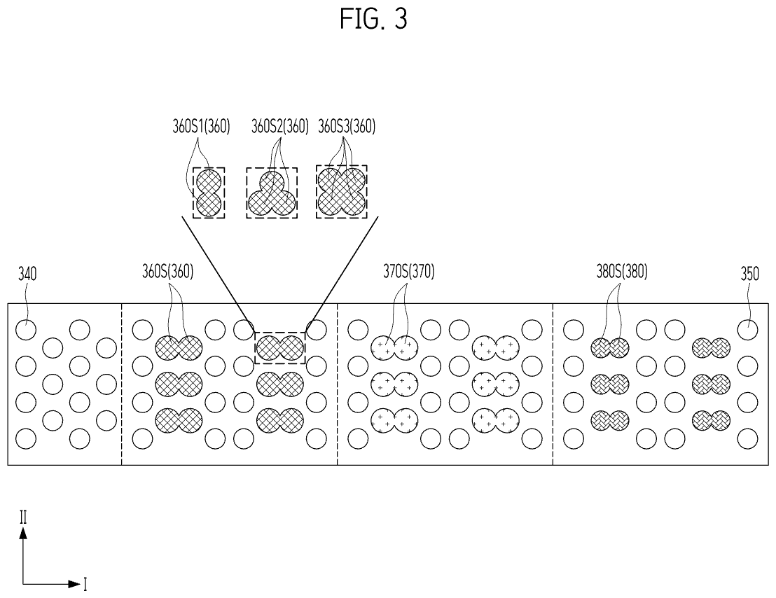

FIG. 3 is a drawing illustrating a semiconductor device of an embodiment of the present disclosure. Hereinafter, content redundant with content already described above is omitted.

Referring to FIG. 3, the semiconductor device may include channel structures 340, supports 350, first contact vias 360, second contact vias 370, and third contact vias 380.

The channel structures 340 may be arranged in a first direction I and a second direction II intersecting the first direction I. For example, the channel structures 340 may be arranged in a checkerboard pattern. However, the arrangement pattern of the channel structures 340 is not limited thereto.

The supports 350 may be positioned spaced apart from the channel structures 340. The supports 350 may be arranged in the first direction I or the second direction II. For example, the supports 350 may be successively arranged spaced apart from each other in the first direction I. Alternatively, the supports 350 may be successively arranged spaced apart from each other in the second direction II. However, the arrangement pattern of the supports 350 is not limited thereto.

The first contact vias 360 may include first sub-vias 360S merged in the horizontal or first direction I. The second contact vias 370 may include second sub-vias 370S merged in the horizontal or first direction I. The third contact vias 380 may include third sub-vias 380S merged in the horizontal or first direction I. The first, second, and third contact vias 360, 370, and 380 may be positioned between the supports 350, respectively.

According to an embodiment of the present disclosure, the first, second, and third contact vias 360, 370, and 380 may include the first, second, and third sub-vias 360S, 370S, and 380S merged in the horizontal or first direction I, respectively. Here, the first, second, and third sub-vias 360S, 370S, and 380S may be two or more in number. Therefore, the first, second, and third contact vias 360, 370, and 380 may have various shapes.

A first contact via 360 may include two first sub-vias 360S merged in the horizontal direction. For example, the first contact via 360 may include two first sub-vias 360S merged in the first direction I. Alternatively, a first contact via 360 may include two first sub-vias 360S1 merged in the second direction II. In this case, in a plane defined by the first direction I and the second direction II, the first contact via 360 may have a dumbbell shape. However, the present disclosure is not limited thereto, and the first contact via 360 may include two first sub-vias merged in a third direction intersecting the first direction I and the second direction II. Here, the third direction may refer to a diagonal direction with respect to the first direction I and the second direction II.

A first contact via 360 may include three or more first sub-vias 360S2 and 360S3 merged in the horizontal or first direction I. As an example, the first contact via 360 may include three first sub-vias 360S2 merged in the horizontal or first direction I. In this case, the first contact via 360 may have a three-leaf clover shape in the plane. As another example, a first contact via 360 may include four first sub-vias 360S3 merged in the horizontal or first direction I. In this case, the first contact via 360 may have a four-leaf clover shape. In addition, in a case where the first contact via 360 includes three or more merged first sub-vias 360S2, 360S3, the first contact via 360 may have a width greater than that of a case where two first sub-vias 360S and 360S1 are merged.

Similarly, the second and third contact vias 370 and 380 may include two or more second and third sub-vias 370S and 380S merged in the horizontal or first direction I. In this case, the second and third contact vias 370 and 380 may have a dumbbell shape or a clover shape in the plane. In addition, the first, second and third contact vias 360, 370, and 380 may have different numbers of merged first, second and third sub-vias 360S, 370S, and 380S. For example, in the first contact via 360, three first sub-vias 360S2 may be merged, and in the second and third contact vias 370 and 380, two first sub-vias 370S may be merged.

According to the structure described above, the first, second, and third contact vias 360, 370, and 380 may have various shapes by varying the number of merged first, second, and third sub-vias 360S, 370S, and 380S.

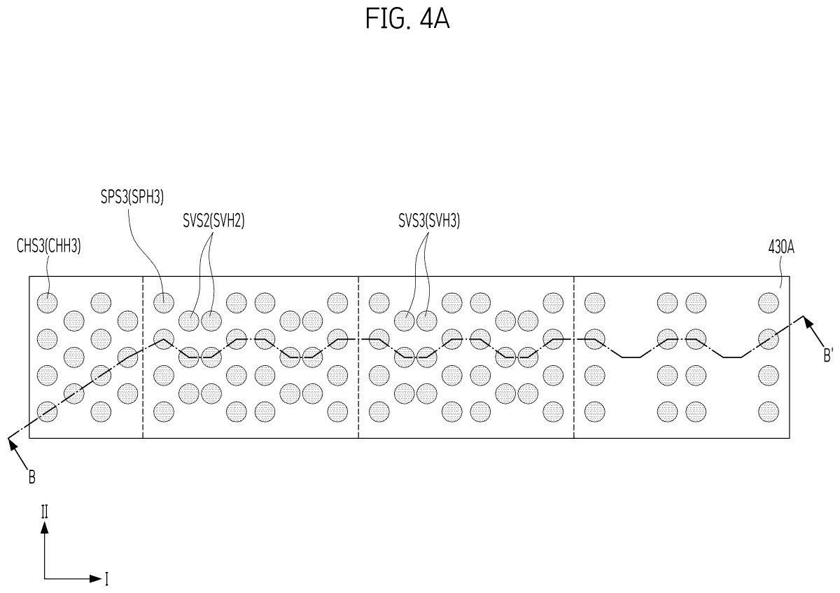

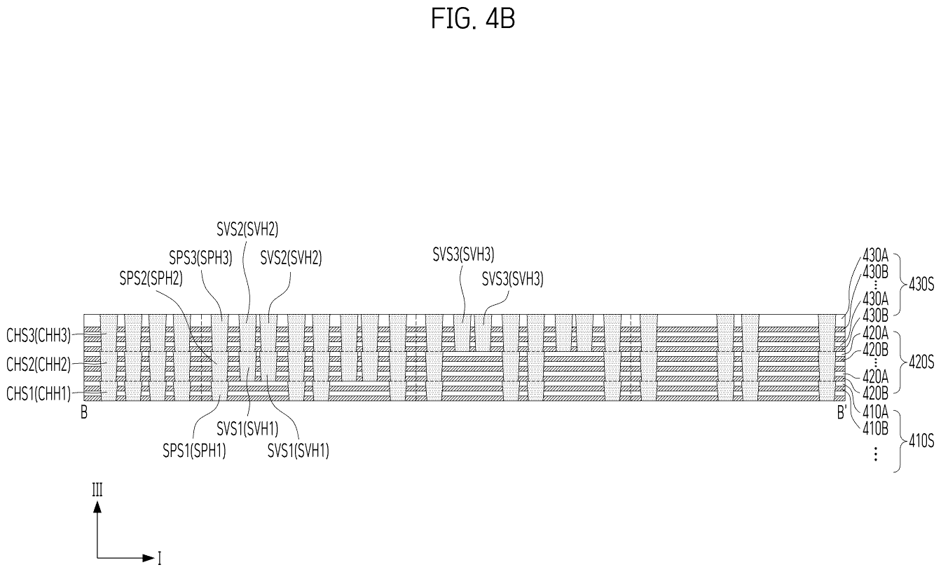

FIGS. 4A, 4B, 5A, 5B, 6A, 6B, 7A, 7B, 8A, 8B, 9A, 9B, 10A, and 10B are drawings illustrating a method of manufacturing a semiconductor device according to an embodiment of the present disclosure. FIGS. 4A, 5A, 6A, 7A, 8A, 9A, and 10A are plan views, and FIGS. 4B, 5B, 6B, 7B, 8B, 9B, and 10B are cross-sectional views taken along line B-B′ in each of FIGS. 4A, 5A, 6A, 7A, 8A, 9A, and 10A, respectively. Hereinafter, content redundant with content already described above is omitted.

Referring to FIGS. 4A and 4B, a first stack 410S may be formed by alternately stacking first material layers 410A and second material layers 410B. The first material layers 410A and the second material layers 410B may include different materials. For example, the first material layers 410A and the second material layers 410B may include materials having different etching selectivities. The first material layers 410A may include an insulating material, such as an oxide, and the second material layers 410B may include a sacrificial material, such as a nitride. Alternatively, the second material layers 410B may include a conductive material, such as tungsten, molybdenum, or polysilicon.

Subsequently, first channel holes CHH1 extending through the first stack 410S may be formed. First support holes SPH1 extending through the first stack 410S may be formed. When forming the first channel holes CHH1, the first support holes SPH1 may be formed. Subsequently, a sacrificial material may be formed in the first channel holes CHH1 and the first support holes SPH1. Here, the sacrificial material may include a sacrificial material, such as tungsten or carbon. Accordingly, first channel sacrificial layers CHS1 may be formed in the first channel holes CHH1, and first support sacrificial layers SPS1 may be formed in the first support holes SPH1.

Subsequently, a second stack 420S may be formed by alternately stacking third material layers 420A and fourth material layers 420B on the first stack 410S. The third material layers 420A may include substantially the same material as the first material layers 410A. The fourth material layers 420B may include substantially the same material as the second material layers 410B.

Subsequently, second channel holes CHH2 connected to the first channel holes CHH1 and extending through the second stack 420S may be formed. Here, the second channel holes CHH2 may expose the first channel sacrificial layers CHS1. Second support holes SPH2 connected to the first support holes SPH1 through the second stack 420S may be formed. Here, the second support holes SPH2 may expose the first support sacrificial layers SPS1. First sub-via holes SVH1 extending through the second stack 420S may be formed. Here, two or more first sub-via holes SVH1 may be formed adjacent to each other. The first sub-via holes SVH1 may expose the first stack 410S.

When forming the second channel holes CHH2, the second support holes SPH2 and/or the first sub-via holes SVH1 may be formed. In other words, channel holes for forming channel structures, support holes for forming supports, and sub-via holes for forming contact vias may be formed simultaneously. In this case, the manufacturing cost of the semiconductor device may be reduced by unifying a process of forming holes for different structures.

Subsequently, a sacrificial material, such as tungsten or carbon may, be formed in the second channel holes CHH2, the second support holes SPH2, and the first sub-via holes SVH1. Accordingly, second channel sacrificial layers CHS2 may be formed in the second channel holes CHH2, second support sacrificial layers SPS2 may be formed in the second support holes SPH2, and first sub-via sacrificial layers SVS1 may be formed in the first sub-via holes SVH1.

Subsequently, a third stack 430S may be formed by alternately stacking fifth material layers 430A and sixth material layers 430B on the second stack 420S. The fifth material layers 430A may include substantially the same material as the first material layers 410A. The sixth material layers 430B may include substantially the same material as the second material layers 410B.

Subsequently, third channel holes CHH3 connected to the second channel holes CHH2 and extending through the third stack 430S may be formed. Here, the third channel holes CHH3 may expose the second channel sacrificial layers CHS2. Third support holes SPH3 connected to the second support holes SPH2 through the third stack 430S may be formed. Here, the third support holes SPH3 may expose the second support sacrificial layers SPS2.

Second sub-via holes SVH2 connected to the first sub-via holes SVH1 through the third stack 430S may be formed. Here, the second sub-via holes SVH2 may expose the first sub-via sacrificial layers SVS1. Third sub-via holes SVH3 extending through the third stack 430S may be formed. Here, two or more third sub-via holes SVH3 may be formed adjacent to each other. The third sub-via holes SHV3 may expose the second stack 420S. When forming the third channel holes CHH3, the third support holes SPH3, the second sub-via holes SVH2, and the third sub-via holes SVH3 may be formed.

Subsequently, a sacrificial material, such as tungsten or carbon, may be formed in the third channel holes CHH3, the third support holes SPH3, the second sub-via holes SVH2, and the third sub-via holes SVH3. Accordingly, third channel sacrificial layers CHS3 may be formed in the third channel holes CHH3, third support sacrificial layers SPS3 may be formed in the third support holes SPH3, second sub-via sacrificial layers SVS2 may be formed in the second sub-via holes SVH2, and third sub-via sacrificial layers SVS3 may be formed in the third sub-via holes SVH3.

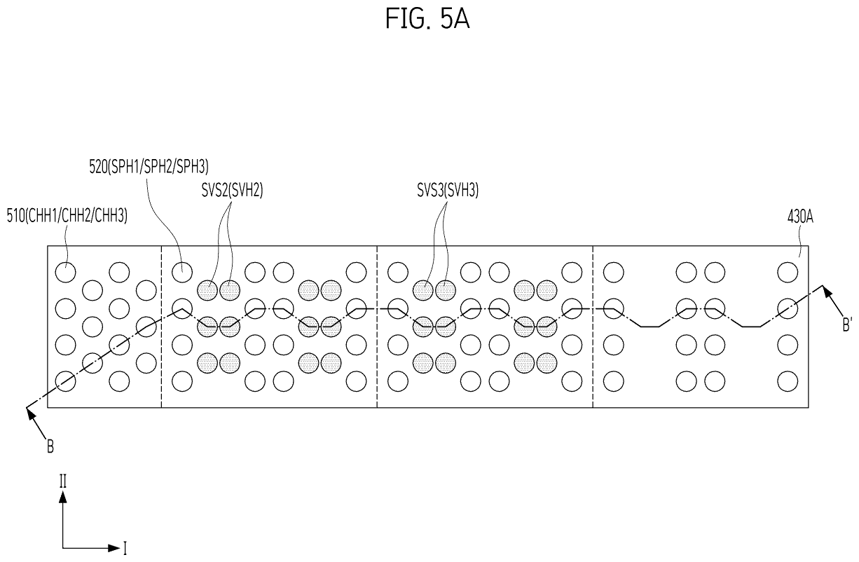

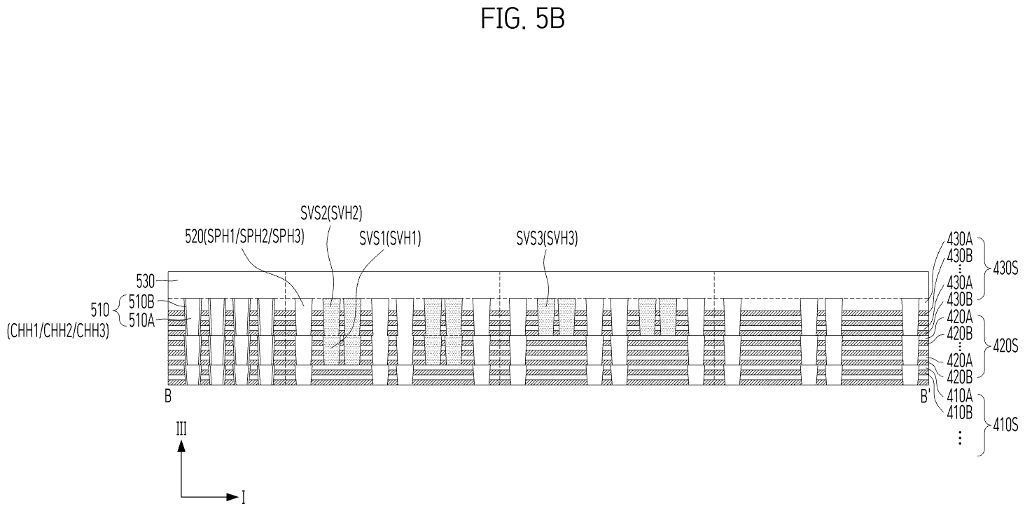

Referring to FIGS. 5A and 5B, channel structures 510 and supports 520 may be formed. Initially, the first, second, and third channel sacrificial layers CHS1, CHS2, and CHS3 formed in the first, second, and third channel holes CHH1, CHH2, and CHH3 may be removed. Subsequently, a memory layer 510B and a channel layer 510A may be formed in the first, second, and third channel holes CHH1, CHH2, and CHH3. Accordingly, the channel structures 510 including the channel layer 510A and the memory layer 510B surrounding the channel layer 510A may be formed.

The first, second, and third support sacrificial layers SPS1, SPS2, and SPS3 formed in the first, second, and third support holes SPH1, SPH2, and SPH3 may be removed. Subsequently, the supports 520 may be formed in the first, second, and third support holes SPH1, SPH2, and SPH3. When forming the channel structures 510, the supports 520 may be formed. In this case, the supports 520 may have a structure similar to the channel structures 510. For example, the supports 520 may include a dummy channel layer and a dummy memory layer.

However, the present disclosure is not limited thereto, and the supports 520 may be separately formed. In this case, the supports 520 may include an insulating material, such as an oxide. In addition, the supports 520 may include a conductive layer, such as tungsten, and an insulating layer covering the conductive layer.

Subsequently, an interlayer insulating layer 530 may be formed on the third stack 430S. Here, the interlayer insulating layer 530 may include an insulating material, such as an oxide.

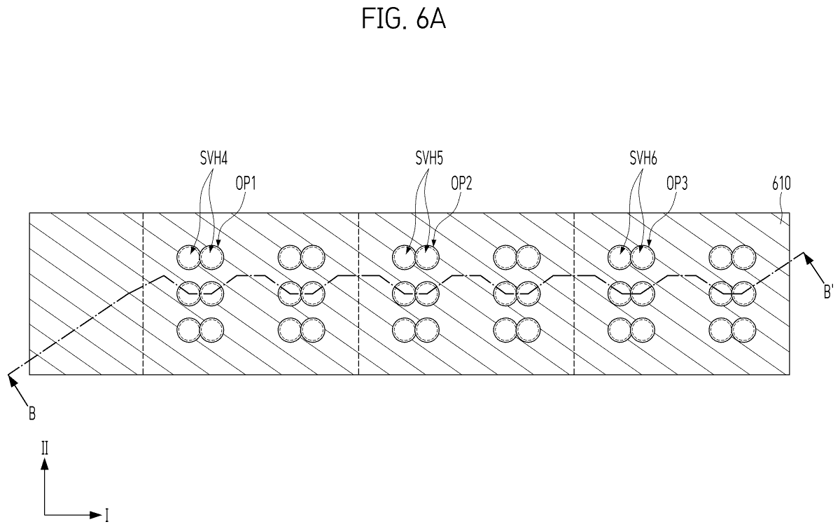

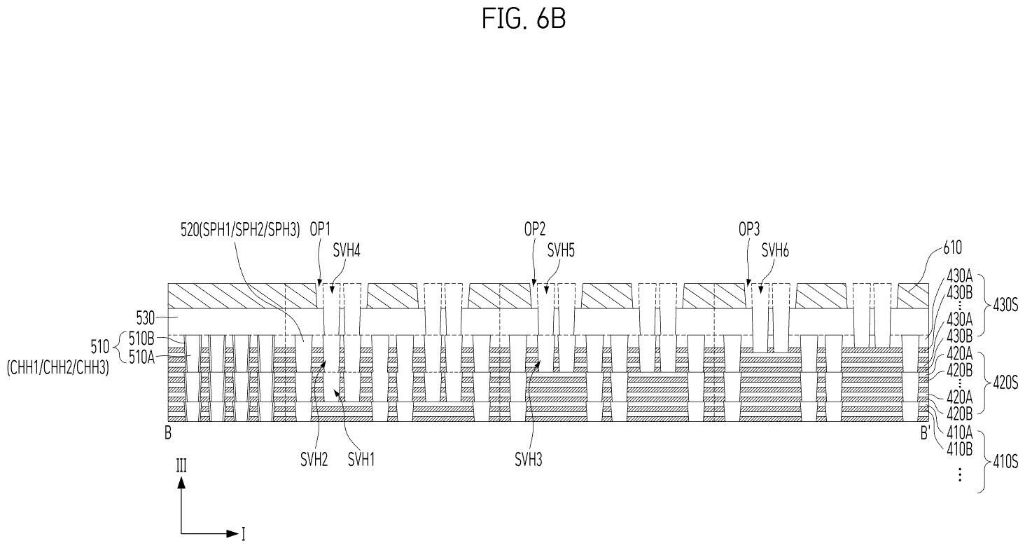

Referring to FIGS. 6A and 6B, a protective layer 610 may be formed. The protective layer 610 may prevent the channel structures 510 and the supports 520 from being damaged in a process of forming contact vias in a subsequent process. The protective layer 610 may include a material different from that of the first, second, and third stacks 410S, 420S, and 430S and the interlayer insulating layer 530. For example, the protective layer 610 may include polysilicon or the like.

Subsequently, fourth sub-via holes SVH4 connected to the second sub-via holes SVH2 through the protective layer 610 may be formed. Here, the fourth sub-via holes SVH4 may expose the second sub-via sacrificial layers SVS2 shown in FIG. 5B. Fifth sub-via holes SVH5 connected to the third sub-via holes SVH3 through the protective layer 610 may be formed. Here, the fifth sub-via holes SVH5 may expose the third sub-via sacrificial layers SVS3 shown in FIG. 5B. Sixth sub-via holes SVH6 extending through the protective layer 610 may be formed. For example, the sixth sub-via holes SVH6 extending through the protective layer 610, the interlayer insulating layer 530, and the third stack 430S may be formed. When forming the fourth sub-via holes SHV4, the fifth sub-via holes SVH5 and/or the sixth sub-via holes SVH6 may be formed.

Subsequently, the first and second sub-via sacrificial layers SVS1 and SVS2 may be removed through the fourth sub-via holes SVH4. The third sub-via sacrificial layers SVS3 may be removed through the fifth sub-via holes SVH5.

Subsequently, first openings OP1 may be formed by removing a portion of the protective layer 610 so that at least two fourth sub-via holes SVH4 are interconnected. Second openings OP2 may be formed by removing a portion of the protective layer 610 so that at least two fifth sub-via holes SVH5 are interconnected. Third openings OP3 may be formed by removing a portion of the protective layer 610 so that at least two sixth sub-via holes SVH6 are interconnected. For example, the first, second, and third openings OP1, OP2, and OP3 may be formed by selectively removing the protective layer 610 by using an etching selectivity of the protective layer 610 and the interlayer insulating layer 530. When forming the first openings OP1, the second and third openings OP2 and OP3 may be formed.

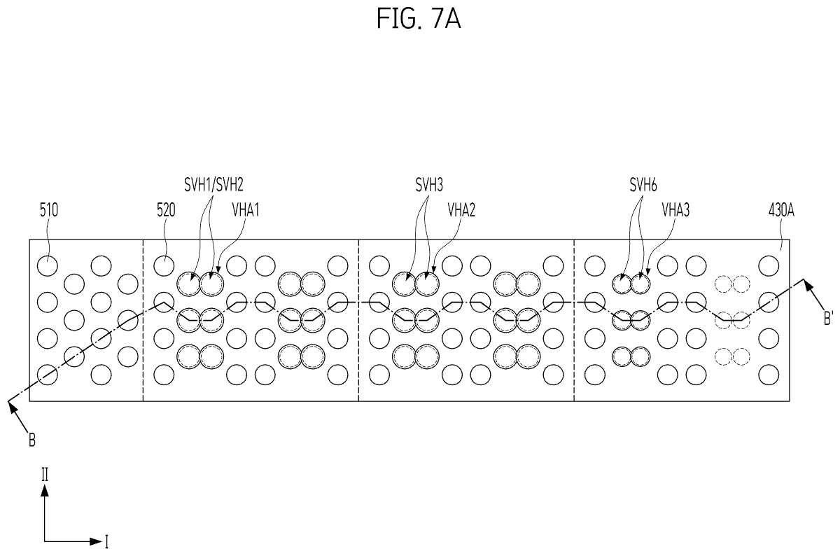

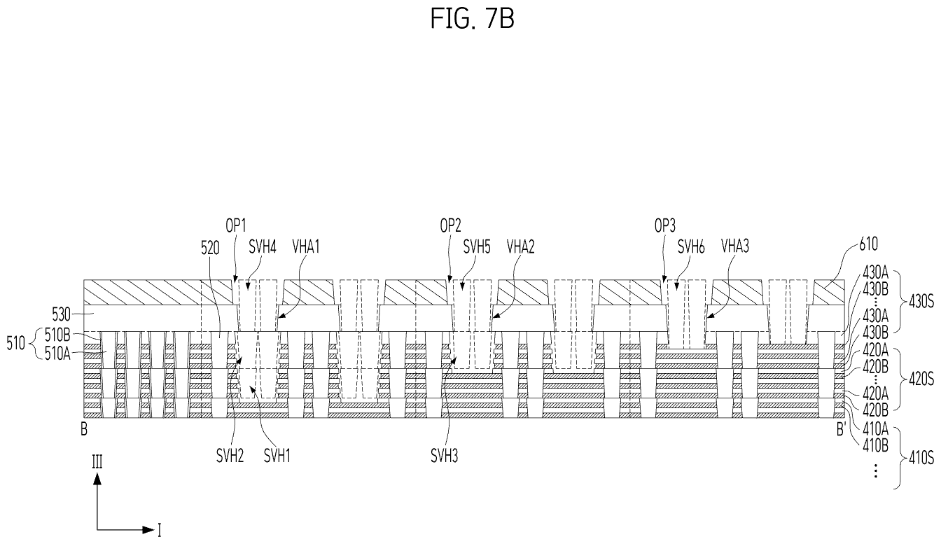

Referring to FIGS. 7A and 7B, preliminary first via holes VHA1 may be formed through the first opening OP1. For example, the first sub-via holes SVH1 may be expanded so that at least two first sub-via holes SVH1 are interconnected, the second sub-via holes SVH2 may be expanded so that at least two second sub-via holes SVH2 are interconnected, and the fourth sub-via holes SVH4 may be expanded so that at least two fourth sub-via holes SHV4 are interconnected. Accordingly, the preliminary first via holes VHA1 including the expanded first, second, and fourth sub-via holes sub-via holes SVH1, SVH2, and SVH4 may be formed.

First, the interlayer insulating layer 530, the fifth material layers 430A, the third material layers 420A, and the first material layers 410A may be selectively removed. For example, the interlayer insulating layer 530, and the fifth, third, and first material layers 430A, 420A, and 410A may be selectively removed so that the first, second, and fourth sub-via holes SVH1, SVH2, and SVH4 are expanded in the first direction I. Subsequently, the sixth material layers 430B, the fourth material layers 420B, and the second material layers 410B may be selectively removed. For example, the fourth, second, and first material layers 430B, 420B, and 410B may be selectively removed so that the first, second, and fourth sub-via holes SVH1, SVH2, and SVH4 may be expanded in the first direction I. Here, levels corresponding to the fourth, second, and first material layers 430B, 420B, and 410B may be expanded more than levels corresponding to the fifth, third, and first material layers 430A, 420A, and 410A.

However, the present disclosure is not limited thereto, and an order of a process of expanding the first, second, and fourth sub-via holes SVH1, SVH2, and SVH4 by selectively removing the interlayer insulating layer 530, and the fifth, third, and first material layers 430A, 420A, and 410A and a process of expanding the first, second, and fourth sub-via holes SVH1, SVH2, and SVH4 by selectively removing the fourth, second, and first material layers 430B, 420B, and 410B may be changed.

In a method of forming the preliminary first via holes VHA1, preliminary second via holes VHA2 and preliminary third via holes VHA3 may be formed. For example, the third sub-via holes SVH3 may be expanded so that at least two third sub-via holes SVH3 are interconnected through the second opening OP2, and the fifth sub-via holes SVH5 may be expanded so that at least two fifth sub-via holes SHV5 are interconnected. Accordingly, the preliminary second via holes VHA2 including the expanded third and fifth sub-via holes SVH3 and SVH5 may be formed. In addition, the preliminary third via holes VHA3 including the expanded sixth sub-via holes SVH6 may be formed, by expanding the sixth sub-via holes SVH6 so that at least two sixth sub-via holes SVH6 are interconnected through the third opening OP3.

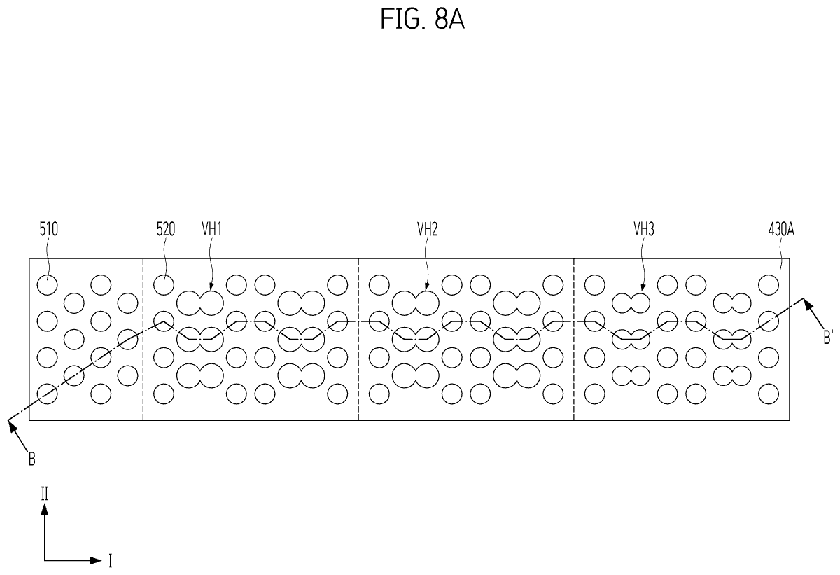

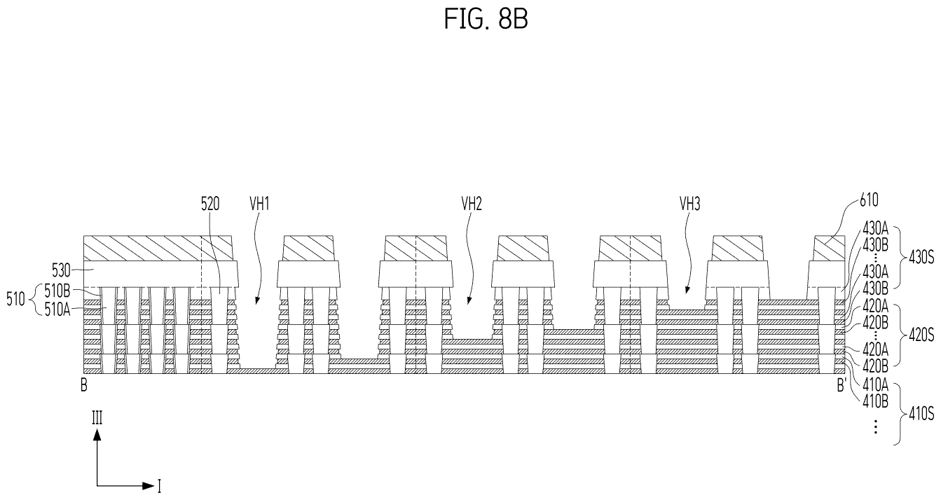

Referring to FIGS. 8A and 8B, first via holes VH1 may be formed. For example, the first via holes VH1 of different depths may be formed by extending the preliminary first via holes VHA1 into the first stack 410S. Here, the first via holes VH1 may expose at least one of the second material layers 410B of the first stack 410S. Therefore, the first via holes VH1 may respectively expose the second material layers 410B and may have different depths.

Initially, a first step of selectively removing the first material layer 410A may be performed. For example, the first material layer 410A may be selectively removed so that the preliminary first via holes VHA1 extend in a third direction III intersecting both the first direction I and the second direction II. Here, the third direction III may be a direction in which the stacks 410S, 420S, and 430S are stacked, and may refer to a vertical direction. In other words, only one layer of the first material layer 410A might be selectively removed.

Subsequently, a second step of selectively removing the second material layer 410B may be performed. In other words, only one layer of the second material layer 410B might be selectively removed. The first via holes VH1 of a target depth may be formed, by repeatedly performing the first and second steps. In other words, target depths of different first via holes VH1 may be different from each other, and the number of repetitions for selectively removing the first and second material layers 410B may be different.

In a method of forming the first via holes VH1, second via holes VH2 and third via holes VH3 may be formed. For example, the second via holes VH2 of different depths may be formed by extending the preliminary second via holes VHA2 into the second stack 420S. In addition, the third via holes VH3 of different depths may be formed by extending the preliminary third via holes VHA3 into the third stack 430S.

According to an embodiment of the present disclosure, the first via holes VH1 of different depths respectively exposing the second material layers 410B in the first stack 410S may be formed by extending the preliminary first via holes VHA1 in the vertical direction. Similarly, the second via holes VH2 of different depths and the third via holes VH3 of different depths may be formed. Even though a height of the stacks 410S, 420S, and 430S increases, according to an embodiment of the present disclosure, because the preliminary first, second, and third via holes VHA1, VHA2, and VHA3 of which a width is greater in the horizontal direction may be formed, the first, second, and third via holes VH1, VH2, and VH3 may be formed to a deep depth in the vertical direction.

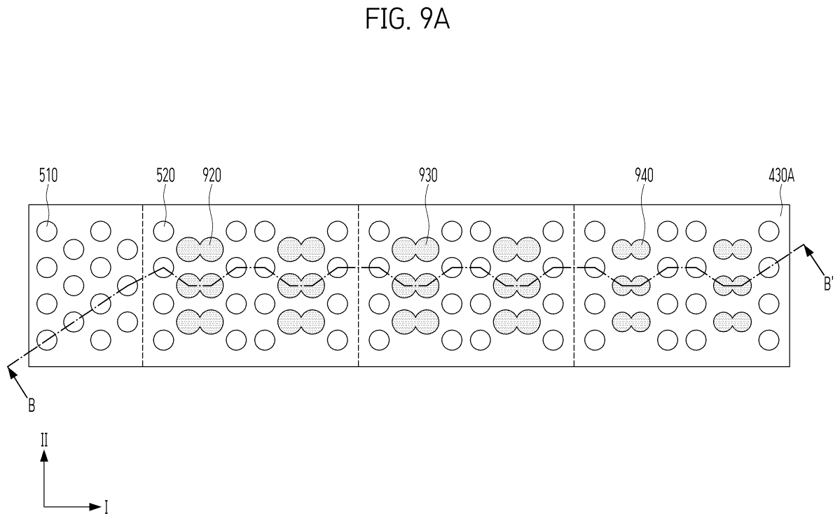

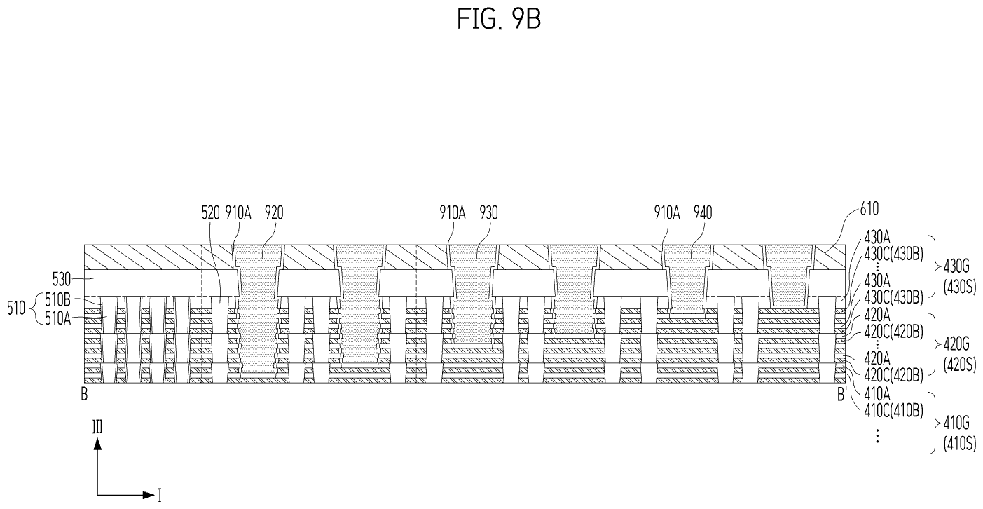

Referring to FIGS. 9A and 9B, an insulating layer 910A may be formed in the first, second, and third via holes VH1, VH2, and VH3. For example, the insulating layer 910A may be conformally formed in the first, second, and third via holes VH1, VH2, and VH3. Here, the insulating layer 910A may include an insulating material, such as an oxide.

Subsequently, first, second, and third via sacrificial layers 920, 930, and 940 may be formed in the first, second, and third via holes VH1, VH2, and VH3. Here, the first, second, and third via sacrificial layers 920, 930, and 940 may include a sacrificial material, such as tungsten or carbon.

Subsequently, a slit (not shown) extending through the stacks 410S, 420S, and 430S may be formed. Subsequently, after removing the second material layers 410B, the fourth material layers 420B, and the sixth material layers 430B through the slit, first, second, and third conductive layers 410C, 420C, and 430C, respectively, may be formed in the area from which the second, fourth, and sixth material layers 410B, 420B, and 430B were removed. Here, the first, second, and third conductive layers 410C, 420C, and 430C may be used as a gate line, such as a source selection line, a word line, or a drain selection line. Accordingly, the stacks 410S, 420S, and 430S may be replaced with first, second, and third gate structures 410G, 420G, and 430G. However, when the second, fourth, and sixth material layers 410B, 420B, and 430B include a conductive material, a process of replacing the stacks 410S, 420S, and 430S with the first, second, and third gate structures 410G, 420G, and 430G may be omitted. In this case, the first, second, and third stacks 410S, 420S, and 430S may be used as a gate structure.

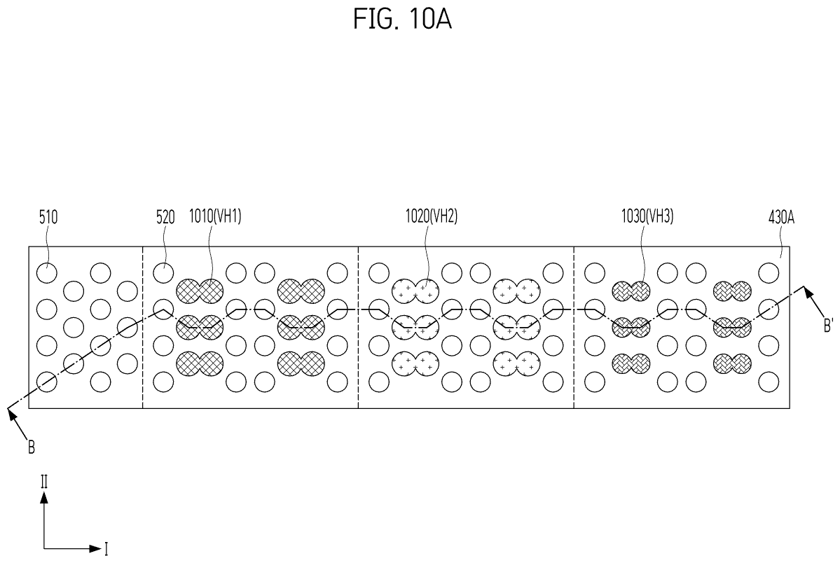

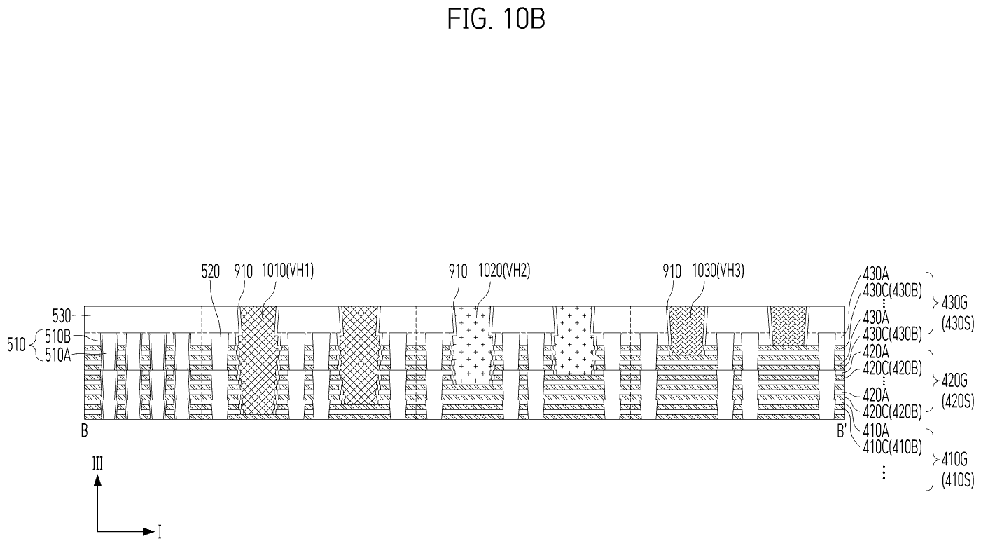

Referring to FIGS. 10A and 10B, the first, second, and third via holes VH1, VH2, and VH3 may be reopened by removing the first, second, and third via sacrificial layers 920, 930, and 940. Subsequently, insulating spacers 910 may be formed by removing the insulating layers 910A formed on a lower surface of the first, second, and third via holes VH1, VH2, and VH3. Here, the insulating spacers 910 may be used to insulate contact vias and remaining conductive layers except for the first, second, and third conductive layers 410C, 420C, and 430C connected to first, second, and third contact vias 1010, 1020, and 1030.

Subsequently, the first contact vias 1010 may be formed in the first via holes VH1. The second contact vias 1020 may be formed in the second via holes VH2. The third contact vias 1030 may be formed in the third via holes VH3. For example, the first, second, and third contact vias 1010, 1020, and 1030 may be formed by forming a conductive material in the first, second, and third via holes VH1, VH2, and VH3. Here, the conductive material may include tungsten or the like.

To improve the degree of integration of the semiconductor device, the number of first, second, and third conductive layers 410C, 420C, and 430C of the first, second, and third gate structures 410G, 420G, and 430G may increase, and a height of the first, second, and third gate structures 410G, 420G, and 430G may increase accordingly. In this case, the number of first, second, and third contact vias 1010, 1020, and 1030 respectively connected to the first, second, and third conductive layers 410C, 420C, and 430C of the first, second, and third gate structures 410G, 420G, and 430G may increase, and a height of the first, second, and third contact vias 1010, 1020, and 1030 may increase.

When a width of an upper surface of preliminary first, second, and third via holes SVA1, SVA2, and SVHA3 is not sufficient in a process of forming the first, second, and third contact vias 1010, 1020, and 1030, a limit exists in forming the first, second, and third via holes VH1, VH2, and VH3 to a desired depth. In other words, the first, second, and third via holes VH1, VH2, and VH3 that are required to be formed to a deep depth may deviate from a target depth or might not be formed with a sufficient width, and the first, second, and third conductive layers 410C, 420C, and 430C, and the first, second, and third contact vias 1010, 1020, and 1030 might not be connected to each other. Therefore, to connect the first, second, and third contact vias 1010, 1020, and 1030 to the first, second, and third conductive layers 410C, 420C, and 430C positioned in a relatively lower portion in the first, second, and third gate structures 410G, 420G, and 430G, the width of the preliminary first, second, and third via holes VHA1, VHA2, and VHA3 is required to be increased.

According to an embodiment of the present disclosure, the preliminary first via hole VHA1 of which a width is increased in the horizontal direction by expanding and merging the first, second, and fourth sub-via holes SVH1, SVH2, and SVH4 may be formed. By a similar method, the preliminary second via holes VHA2 of which a width is increased and the preliminary third via holes VHA3 of which a width is increased in the horizontal direction may be formed. In other words, the preliminary first, second, and third via holes VHA1, VHA2, and VHA3 may be formed to a relatively great width, and the first, second, and third via holes VH1, VH2, and VH3 may be formed by extending the first, second, and third via holes VH1, VH2, and VH3 to a desired depth.

According to the manufacturing method described above, the first, second, and third preliminary via holes VHA1, VHA2, and VHA3 of which a width is expanded in the horizontal direction may be formed, and the first, second, and third via holes VH1, VH2, and VH3 extended to a deep depth in the vertical direction may be formed. In other words, even though a height of the stacks 410S, 420S, and 430S increases, the first, second, and third via holes VH1, VH2, and VH3 may be formed to a target depth.

In addition, when forming the channel holes CHH1, CHH2, and CHH3, the support holes SPH1, SPH2, and SPH3 and the sub-via holes SVH1, SVH2, SVH3, SVH4, SVH5, and SVH6 may be formed. In other words, manufacturing costs of semiconductor devices may be reduced by unifying a process of forming holes for forming different structures.

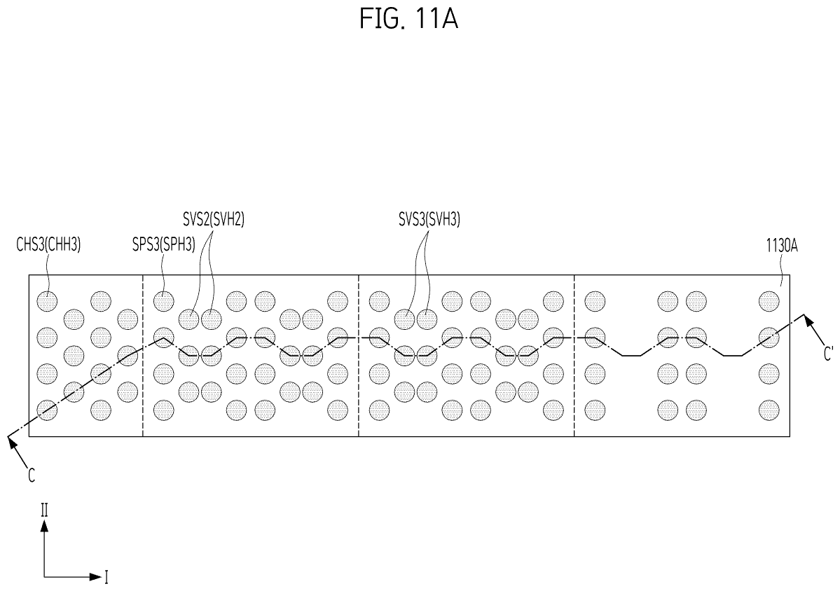

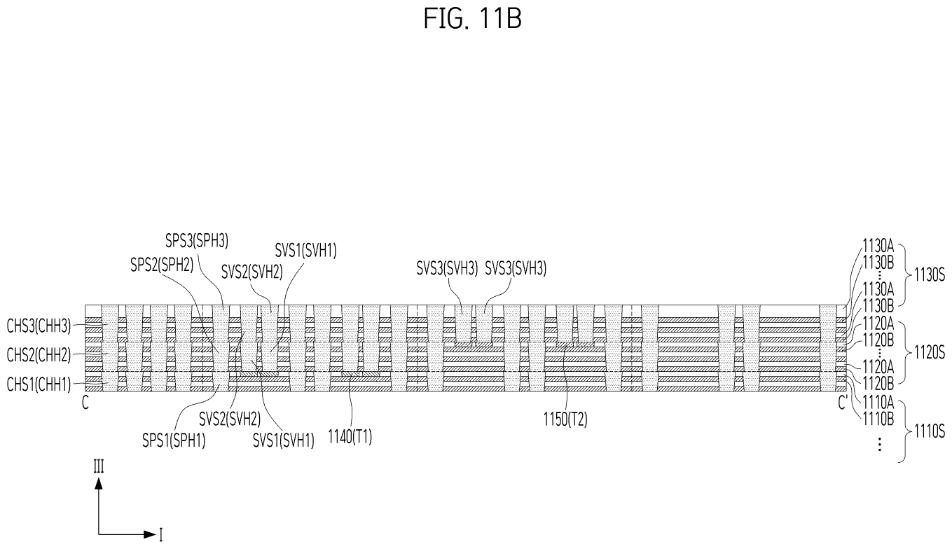

FIGS. 11A, 11B, 12A, 12B, 13A, 13B, 14A, and 14B are drawings illustrating a method of manufacturing a semiconductor device according to an embodiment of the present disclosure. FIGS. 11A, 12A, 13A, and 14A are plan views, and FIGS. 11B, 12B, 13B, and 14B are respective cross-sectional views taken along line C-C′ of respective FIGS. A. Hereinafter, content redundant with content already described above is omitted.

Referring to FIGS. 11A and 11B, a first stack 1110S may be formed by alternately stacking first material layers 1110A and second material layers 1110B. The first material layers 1110A and second material layers 1110B may include different materials. For example, the first material layers 1110A may include an insulating material, such as an oxide, and the second material layers 1110B may include a sacrificial material, such as a nitride, or may include a conductive material, such as tungsten, molybdenum, or polysilicon.

First channel holes CHH1 extending through the first stack 1110S may be formed. First support holes SPH1 extending through the first stack 1110S may be formed. When forming the first channel holes CHH1, the first support holes SPH1 may be formed.

First trenches T1 may be formed at a position respectively corresponding to the first sub-via holes SVH1 in the first stack 1110S. The first trenches T1 may pass through a portion of the first stack 1110S. For example, the first trenches T1 may pass through the first material layers 1110A positioned at the uppermost portion among the first material layers 1110A.

Subsequently, a sacrificial material may be formed in the first channel holes CHH1, the first support holes SPH1, and the first trenches T1. Here, the sacrificial material may include a sacrificial material, such as tungsten or carbon. Accordingly, first channel sacrificial layers CHS1 may be formed in the first channel holes CHH1, and first support sacrificial layers SPS1 may be formed in the first support holes SPH1. In addition, first buffer layers 1140 may be formed in the first trenches T1.

Subsequently, a second stack 1120S may be formed by alternately stacking third material layers 1120A and fourth material layers 1120B on the first stack 1110S. The third material layers 1120A may include substantially the same material as the first material layers 1110A. The fourth material layers 1120B may include substantially the same material as the second material layers 1110B.

Subsequently, second channel holes CHH2 connected to the first channel holes CHH1 through the second stack 1120S may be formed. Second support holes SPH2 connected to the first support holes SPH1 through the second stack 1120S may be formed. First sub-via holes SVH1 connected to the first trenches T1 through the second stack 1120S may be formed. Here, two or more first sub-via holes SVH1 may be formed adjacent to each other. The first sub-via holes SVH1 may expose the first buffer layers 1140. When forming the second channel holes CHH2, the second support holes SPH2 and/or the first sub-via holes SVH1 may be formed. Here, the first buffer layers 1140 may be used as an etch stop pattern when forming the first sub-via holes SVH1. In addition, a width of an upper surface of the first buffer layers 1140 may be greater than a width of a lower surface of the first sub-via holes SVH1. Therefore, in forming the first sub-via holes SVH1, a process margin may be secured through the first buffer layers 1140.

In addition, second trenches T2 may be formed at positions respectively corresponding to the third sub-via holes SVH3 in the second stack 1120S. The second trenches T2 may pass through a portion of the second stack 1120S. For example, the second trenches T2 may pass through the third material layer 1120A positioned at the uppermost portion among the third material layers 1120A.

Subsequently, a sacrificial material, such as tungsten or carbon, may be formed in the second channel holes CHH2, the second support holes SPH2, the first sub-via holes SVH1, and the second trenches T2. Accordingly, second channel sacrificial layers CHS2 may be formed in the second channel holes CHH2, second support sacrificial layers SPS2 may be formed in the second support holes SPH2, first sub-via sacrificial layers SVS1 may be formed in the first sub-via holes SVH1, and second buffer layers 1150 may be formed in the second trenches T2.

Subsequently, a third stack 1130S may be formed by alternately stacking fifth material layers 1130A and sixth material layers 1130B on the second stack 1120S. The fifth material layers 1130A may include substantially the same material as the first material layers 1110A. The sixth material layers 1130B may include substantially the same material as the second material layers 1110B.

Subsequently, third channel holes CHH3 connected to the second channel holes CHH2 through the third stack 1130S may be formed. Third support holes SPH3 connected to the second support holes SPH2 through the third stack 1130S may be formed. Second sub-via holes SVH2 connected to the first sub-via holes SVH1 through the third stack 1130S may be formed. Here, the second sub-via holes SVH2 may expose the first sub-via sacrificial layers SVS1. Third sub-via holes SVH3 connected to the second trenches T2 through the third stack 1130S may be formed. Here, two or more third sub-via holes SVH3 may be formed adjacent to each other. The third sub-via holes SVH3 may expose the second buffer layers 1150. When forming the third channel holes CHH3, the third support holes SPH3, the second sub-via holes SVH2, and/or the third sub-via holes SVH3 may be formed. Here, the second buffer layers 1150 may be used as an etch stop pattern when forming the third sub-via holes SVH3. In addition, a width of an upper surface of the second buffer layers 1150 may be greater than a width of a lower surface of the third sub-via holes SVH3. Therefore, in forming the third sub-via holes SVH3, a process margin may be secured through the second buffer layers 1150.

Subsequently, a sacrificial material, such as tungsten or carbon, may be formed in the third channel holes CHH3, the third support holes SPH3, the second sub-via holes SVH2, and the third sub-via holes SVH3. Accordingly, third channel sacrificial layers CHS3 may be formed in the third channel holes CHH3, third support sacrificial layers SPS3 may be formed in the third support holes SPH3, second sub-via sacrificial layers SVS2 may be formed in the second sub-via holes SVH2, and third sub-via sacrificial layers SVS3 may be formed in the third sub-via holes SVH3.

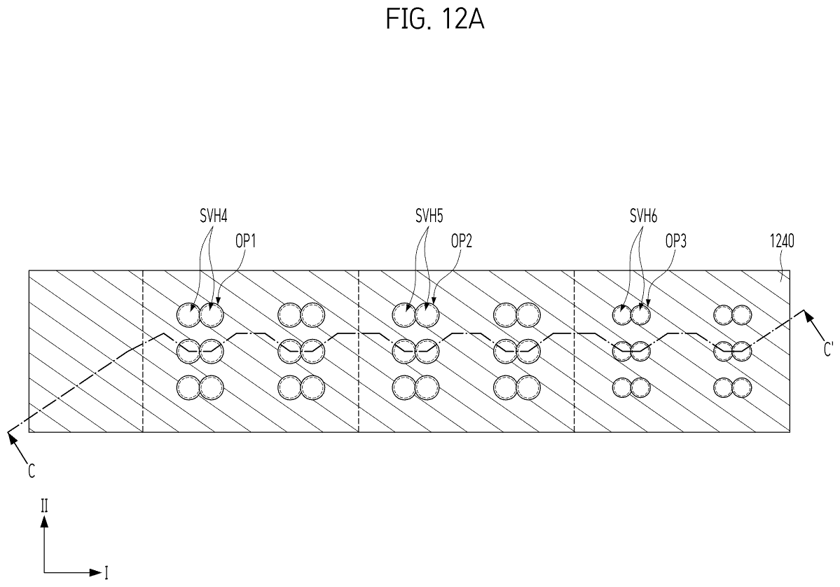

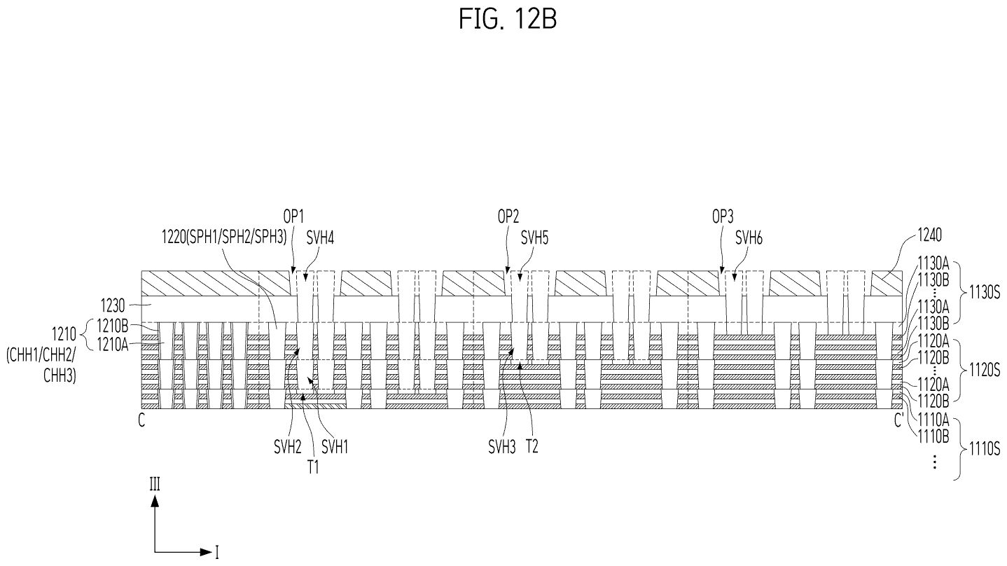

Referring to FIGS. 12A and 12B, channel structures 1210 and supports 1220 may be formed. First, first, second, and third channel sacrificial layers CHS1, CHS2, and CHS3 formed in the first, second, and third channel holes CHH1, CHH2, and CHH3 may be removed. Subsequently, a memory layer 1210B and a channel layer 1210A may be formed in the first, second, and third channel holes CHH1, CHH2, and CHH3. The first, second, and third support sacrificial layers SPS1, SPS2, and SPS3 formed in the first, second, and third support holes SPH1, SPH2, and SPH3 may be removed. Subsequently, the supports 1220 may be formed in the first, second, and third support holes SPH1, SPH2, and SPH3.

Subsequently, an interlayer insulating layer 1230 may be formed on the third stack 1130S. Subsequently, a protective layer 1240 may be formed on the third stack 1130S. The protective layer 1240 may include a material different from that of the first, second, and third stacks 1110S, 1120S, and 1130S, and the interlayer insulating layer 1230. For example, the protective layer 1240 may include a material of polysilicon or the like.

Subsequently, fourth sub-via holes SVH4 connected to second sub-via holes SVH2 through the protective layer 1240 may be formed. Fifth sub-via holes SVH5 connected to third sub-via holes SVH3 through the protective layer 1240 may be formed. Sixth sub-via holes SVH6 extending through the protective layer 1240 may be formed. When forming the fourth sub-via holes SHV4, the fifth sub-via holes SVH5 and/or the sixth sub-via holes SVH6 may be formed.

Subsequently, the first and second sub-via sacrificial layers SVS1 and SVS2 and the first buffer layers 1140 may be removed through the fourth sub-via holes SVH4. In other words, the first and second sub-via holes SVH1 and SVH2 and the first trenches T1 may be reopened through the fourth sub-via holes SVH4.

The third sub-via sacrificial layers SVS3 and the second buffer layers 1150 may be removed through the fifth sub-via holes SVH5. In other words, the third sub-via holes SVH3 and the second trenches T2 may be reopened through the fifth sub-via holes SVH5.

Subsequently, first openings OP1 may be formed by removing a portion of the protective layer 1240 so that at least two fourth sub-via holes SVH4 are interconnected. Second openings OP2 may be formed by removing a portion of the protective layer 1240 so that at least two fifth sub-via holes SVH5 are interconnected. Third openings OP3 may be formed by removing a portion of the protective layer 1240 so that at least two sixth sub-via holes SVH6 are interconnected.

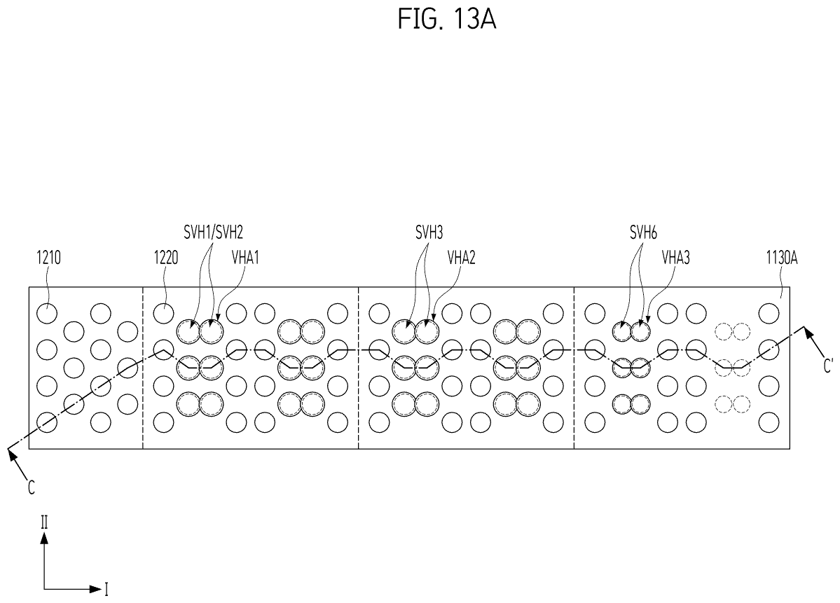

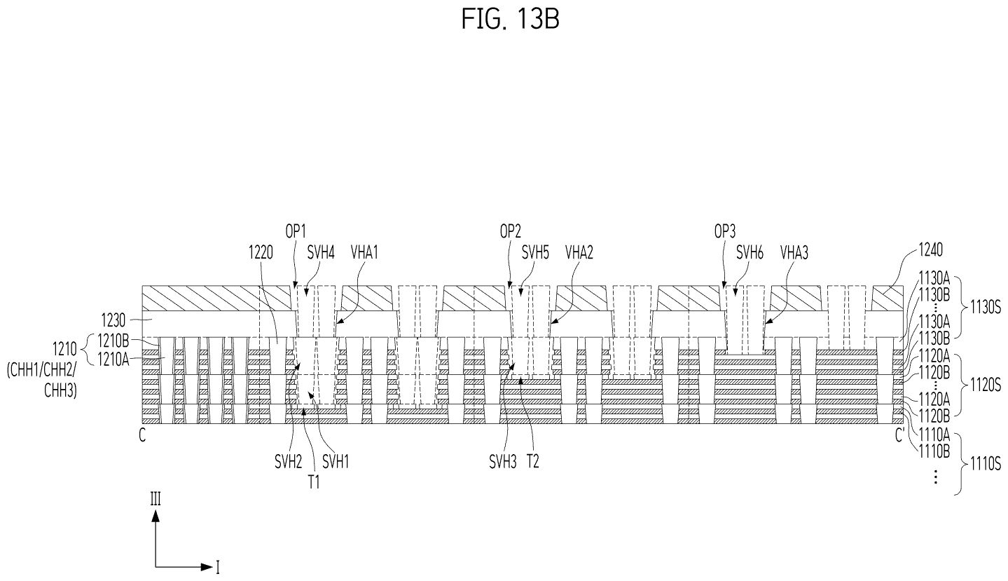

Referring to FIGS. 13A and 13B, the preliminary first via holes VHA1 may be formed through the first opening OP1. For example, the first sub-via holes SVH1 may be expanded so that at least two first sub-via holes SVH1 are interconnected, the second sub-via holes SVH2 may be expanded so that at least two second sub-via holes SVH2 are interconnected, the fourth sub-via holes SVH4 may be expanded so that at least two fourth sub-via holes SHV4 are interconnected, and the first trenches T1 may be expanded so that at least two first trenches T1 are interconnected. Accordingly, the preliminary first via holes VHA1 including the expanded first, second, and fourth sub-via holes SVH1, SVH2, and SVH4 and the expanded first trenches T1 may be formed.

In a method of forming the preliminary first via holes VHA1, the preliminary second via holes VHA2 and the preliminary third via holes VHA3 may be formed. For example, the third sub-via holes SVH3 may be expanded so that at least two third sub-via holes SVH3 are interconnected, the fifth sub-via holes SVH5 may be expanded so that at least two fifth sub-via holes SHV5 are interconnected, and the second trenches T2 may be expanded so that at least two second trenches T2 are interconnected. Accordingly, the preliminary second via holes VHA2 including the expanded third and fifth sub-via holes SVH3 and SVH5 may be formed. In addition, the preliminary third via holes VHA3 including the expanded sixth sub-via holes SVH6 may be formed, by expanding the sixth sub-via holes SVH6 so that at least two sixth sub-via holes SVH6 are interconnected.

According to an embodiment of the present disclosure, the first trenches T1 may be formed at positions respectively corresponding to the first sub-via holes SVH1 in the first stack 1110S, and the second trenches T2 may be formed at positions respectively corresponding to the third sub-via holes SVH3 in the second stack 1120S. Here, an upper surfaces of the first and second trenches T1 and T2 may have a width greater than that of a lower surface of the first and third sub-via holes SVH1 and SHV2.

In addition, in a process of forming the preliminary first and second via holes VHA1 and VHA2, at least two first trenches T1 may be expanded to be interconnected, and at least two second trenches T2 may be expanded to be interconnected. In this case, the preliminary first via hole VHA1 may have a width that is further expanded in the horizontal direction at a boundary surface between the first stack 1110S and the second stack 1120S, and the preliminary second via hole VHA2 may have a width that is further expanded in the horizontal direction at a boundary surface between the second stack 1120S and the third stack 1130S. Therefore, the preliminary first and second via holes VHA1 and VHA2 may be extended to a target depth in a subsequent process, by sufficiently securing a width of the preliminary first and second via holes VHA1 and VHA2 through the first and second trenches T1 and T2.

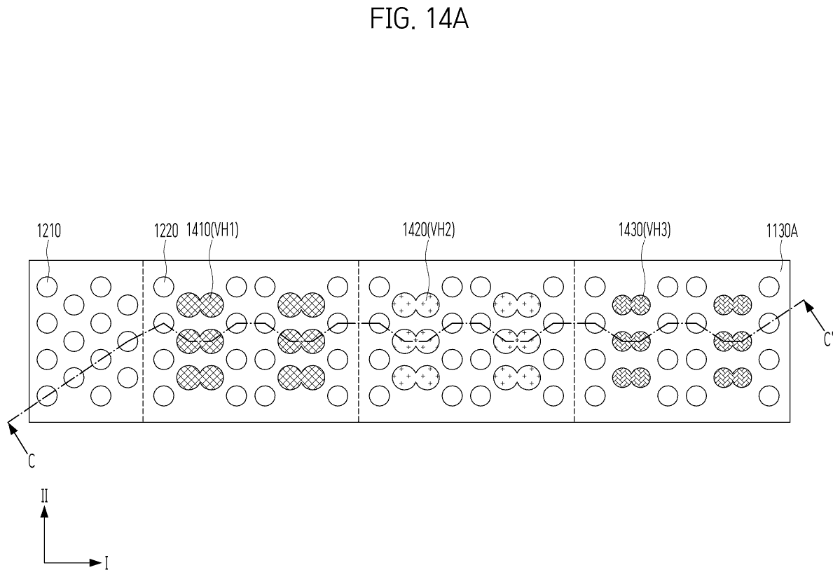

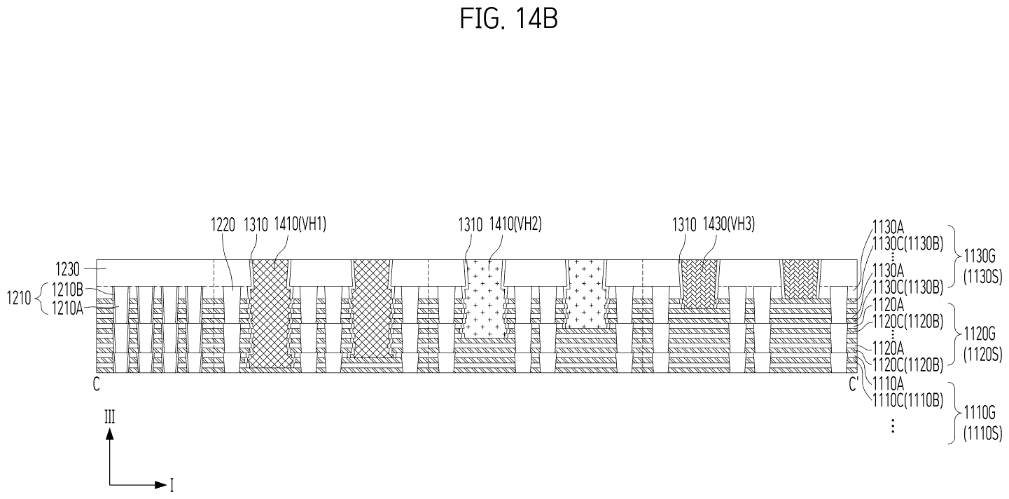

Referring to FIGS. 14A and 14B, the first via holes VH1, the second via holes VH2, and the third via holes VH3 may be formed. For example, with reference to FIGS. 8a and 8b again, the first via holes VH1, the second via holes VH2, and the third via holes VH3 may be formed by the same method.

The first via holes VH1 of different depths may be formed by extending the preliminary first via holes VHA1 into the first stack 1110S. Initially, a first step of selectively removing the first material layer 1110A may be performed. Subsequently, a second step of selectively removing the second material layer 1110B may be performed. By repeating this process, different first via holes VH1 may be formed to different target depths. In a method of forming the first via holes VH1, the second via holes VH2 and the third via holes VH3 may be formed. For example, the second via holes VH2 of different depths may be formed by extending the preliminary second via holes VHA2 into the second stack 1120S. In addition, the third via holes VH3 of different depths may be formed by extending the preliminary third via holes VHA3 into the third stack 1130S.

According to an embodiment of the present disclosure, the first via holes VH1 of different depths respectively exposing the second material layers 1110B in the first stack 1110S may be formed by extending the preliminary first via holes VHA1 in the vertical direction. In a similar method, the second via holes VH2 and the third via holes VH3 may be formed. Here, a target depth of the first and second via holes VH1 and VH2 is deeper than that of the third via holes VH3. According to an embodiment of the present disclosure, because a width of the preliminary first and second via holes VHA1 and VHA2 may be sufficiently secured through the first and second trenches T1 and T2, the first and second via holes VH1 and VH2 may be sufficiently extended to the target depth through this.

Subsequently, with reference to FIGS. 9A to 10B again, first, second, and third gate structures 1110G, 1120G, and 1130G may be formed by replacing the second, fourth, and sixth material layers 1110B, 1120B, and 1130B of the first, second, and third stacks 1110S, 1120S, and 1130S with the first, second, and third conductive layers 1110C, 1120C, and 1130C. In addition, insulating spacers 1310 and first, second, and third contact vias 1410, 1420, and 1430 may be formed in the first, second, and third via holes VH1, VH2, and VH3 and the expanded first and second trenches T1 and T2.

According to the manufacturing method described above, the first and second trenches T1 and T2 may be formed in the first and second stacks 1110S and 1120S, and the first and second buffer layers 1140 and 1150 may be formed in the first and second trenches T1 and T2. Here, the first and second buffer layers 1140 and 1150 may be used as an etch stop pattern in a process of forming the first and third sub-via holes SVH1 and SVH3. In addition, the first and second trenches T1 and T2 may secure a width expanded in the horizontal direction by the first and second trenches T1 and T2 in a process of forming the first and second contact vias 1410 and 1420, thereby forming the first and second contact vias 1410 and 1420 of which a target depth is relatively deep.

Although some embodiments according to the technical spirit of the present disclosure have been described with reference to the accompanying drawings, the present disclosure is not limited to the above-described embodiments. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
a first gate structure including first conductive layers and first insulating layers alternately stacked with each other;
a second gate structure positioned on the first gate structure, the second gate structure including second conductive layers and second insulating layers alternately stacked with each other;
channel structures extending through the first gate structure and the second gate structure, the channel structures having a first width;
first contact vias extending through the second gate structure and into the first gate structure, the first contact vias respectively connected to the first conductive layers, the first contact vias respectively including first sub-vias merged in a horizontal direction, and the first contact vias having a second width greater than the first width; and
second contact vias extending into the second gate structure, the second contact vias respectively connected to the second conductive layers, the second contact vias respectively including second sub-vias merged in the horizontal direction, and the second contact vias having a third width greater than the first width.

2. The semiconductor device of claim 1, wherein at least one of the first contact vias and the second contact vias has a dumbbell shape or a clover shape in a plane.

3. The semiconductor device of claim 1, wherein the first contact vias include a first uneven portion on a sidewall in a plane.

4. The semiconductor device of claim 3, wherein a portion where the first sub-vias are in contact with each other forms a concave portion of the first uneven portion, and
each of the first sub-vias forms a convex portion of the first uneven portion.

5. The semiconductor device of claim 1, wherein the first contact vias include a second uneven portion on a sidewall in a cross-section.

6. The semiconductor device of claim 5, wherein the second uneven portion includes protrusions in which the first contact vias protrude toward the first conductive layers or the second conductive layers.

7. The semiconductor device of claim 1, wherein each of the first contact vias includes at least two of the first sub-vias.

8. The semiconductor device of claim 1, further comprising:
a third gate structure positioned on the second gate structure, the third gate structure including third conductive layers and third insulating layers alternately stacked with each other; and
third contact vias extending into the third gate structure, the third contact vias respectively connected to the third conductive layers, the third contact vias respectively including third sub-vias merged in the horizontal direction, and the third contact vias having a fourth width greater than the first width.

9. The semiconductor device of claim 8, wherein the fourth width is less than at least one of the second width and the third width.

10. The semiconductor device of claim 8, further comprising:
supports extending through the first gate structure, the second gate structure, and the third gate structure; and
an interlayer insulating layer positioned on the third gate structure.

11. The semiconductor device of claim 10, wherein the first contact vias and the second contact vias extend through the third gate structure and the interlayer insulating layer.

12. The semiconductor device of claim 10, wherein the interlayer insulating layer covers the channel structures and the supports.

13. The semiconductor device of claim 1, wherein the third width is substantially the same as the second width.

14. The semiconductor device of claim 1, wherein the first contact vias have a fifth width greater than the second width in the first gate structure.

15. A method of manufacturing a semiconductor device, the method comprising:
forming a first stack by alternately stacking first material layers and second material layers;
forming a second stack by alternately stacking third material layers and fourth material layers on the first stack;
forming first sub-via holes extending through the second stack;
forming preliminary first via holes by expanding the first sub-via holes so that at least two of the first sub-via holes are interconnected;
forming first via holes of different depths by extending the preliminary first via holes into the first stack; and
forming first contact vias in the first via holes.

16. The method of claim 15, wherein forming the preliminary first via holes comprises:
selectively removing the third material layers; and
selectively removing the fourth material layers.

17. The method of claim 15, wherein forming the first via holes comprises:
removing a first material layer of the first material layers;
removing a second material layer of the second material layers; and
forming the first via holes of different depths by removing additional first and second material layers to achieve the different depths.

18. The method of claim 15, wherein the preliminary first via holes are extended so that the first via holes expose the respective second material layers.

19. The method of claim 15, further comprising:
forming a third stack by alternately stacking fifth material layers and sixth material layers on the second stack;
forming second sub-via holes connected to the first sub-via holes through the third stack;
forming a protective layer on the third stack;
forming fourth sub-via holes connected to the second sub-via holes through the protective layer; and
forming first openings by removing a portion of the protective layer so that at least two of the fourth sub-via holes are interconnected.

20. The method of claim 19, wherein the preliminary first via holes are formed through the first openings.

21. The method of claim 19, further comprising:
forming third sub-via holes extending through the third stack;
forming fifth sub-via holes connected to the third sub-via holes through the protective layer;
forming second openings by removing a portion of the protective layer so that at least two of the fifth sub-via holes are interconnected;
forming preliminary second via holes by expanding the third sub-via holes so that at least two of the third sub-via holes are interconnected through the second openings;
forming second via holes of different depths by extending the preliminary second via holes into the second stack; and
forming second contact vias in the second via holes.

22. The method of claim 19, further comprising:
forming sixth sub-via holes extending through the protective layer and the third stack;
forming third openings by removing a portion of the protective layer to so that at least two of the sixth sub-via holes are interconnected;
forming preliminary third via holes by expanding the sixth sub-via holes so that at least two of the sixth sub-via holes are interconnected through the third openings;
forming third via holes of different depths by extending the preliminary third via holes into the third stack; and
forming third contact vias in the third via holes.

23. The method of claim 15, further comprising:
forming first channel holes extending through the first stack;
forming trenches positioned to correspond to the first sub-via holes, respectively, in the first stack; and
forming buffer layers in the trenches.

24. The method of claim 23, wherein the first sub-via holes expose the buffer layers.

25. The method of claim 23, further comprising:
forming second channel holes connected to the first channel holes through the second stack.

26. The method of claim 25, wherein the first sub-via holes are formed when forming the second channel holes.

27. The method of claim 23, further comprising:
reopening the trenches by removing the buffer layers through the first sub-via holes;
expanding the reopened trenches so that at least two of the reopened trenches are interconnected, when expanding the first sub-via holes; and
forming the first contact vias in the first via holes and the expanded trenches.

28. The method of claim 15, wherein the number of the first sub-via holes is two or more.

29. A method of manufacturing a semiconductor device, the method comprising:
forming a first stack;
forming a second stack on the first stack;
forming first sub-via holes extending through the second stack;
forming a third stack on the second stack;
forming second sub-via holes connected to the first sub-via holes through the third stack;
forming a protective layer on the third stack;
forming fourth sub-via holes connected to the second sub-via holes, respectively, through the protective layer;
forming a first opening by expanding the fourth sub-via holes by removing a portion of the protective layer so that at least two of the fourth sub-via holes are interconnected; and
forming a preliminary first via hole by expanding the second sub-via holes and the first sub-via holes through the first opening.

30. The method of claim 29, further comprising:
forming a first via hole by extending the preliminary first via hole into the first stack; and
forming a first contact via in the first via hole.

31. The method of claim 29, further comprising:
forming third sub-via holes extending through the third stack;
forming fifth sub-via holes connected to the third sub-via holes through the protective layer;
forming a second opening by removing a portion of the protective layer so that at least two of the fifth sub-via holes are interconnected;
forming a preliminary second via hole by expanding the third sub-via holes so that at least two of the third sub-via holes are interconnected through the second opening;
forming a second via hole by extending the preliminary second via hole into the second stack; and
forming a second contact via in the second via hole.

32. The method of claim 29, further comprising:
forming sixth sub-via holes extending through the protective layer and the third stack;
forming a third opening by removing a portion of the protective layer so that at least two of the sixth sub-via holes are interconnected;
forming a preliminary third via hole by expanding the sixth sub-via holes so that at least two of the sixth sub-via holes are interconnected through the third opening;
forming a third via hole by extending the third via hole into the third stack; and
forming a third contact via in the third via hole.

33. The method of claim 29, further comprising:
forming a first channel hole extending through the first stack;
forming trenches positioned to correspond to the first sub-via holes, respectively, in the first stack; and
forming buffer layers in the trenches.

34. The method of claim 33, wherein the first sub-via holes expose the buffer layers.

35. The method of claim 33, further comprising:
forming a second channel hole connected to the first channel holes through the second stack.

36. The method of claim 35, wherein the first sub-via holes are formed when forming the second channel holes.

37. The method of claim 33, further comprising:
reopening the trenches by removing the buffer layers through the first sub-via holes;
expanding the reopened trenches so that at least two of the reopened trenches are interconnected, when expanding the first sub-via holes; and
forming the first contact via in the first via hole and the expanded trenches.
